(19) United States
(12) Patent Application Publication
(10) Pub. No.: US 2026/0065953 A1
(43) Pub. Date: Mar. 5, 2026

(54) MEMORY DEVICE

(71) Applicant: Kioxia Corporation, Tokyo (JP)

(72) Inventor: Naoki MATSUSHITA, Seoul (KR)

(73) Assignee: Kioxia Corporation, Tokyo (JP)

(21) Appl. No.: 19/073,686

(22) Filed: Mar. 7, 2025

(30) Foreign Application Priority Data
Sep. 5, 2024 (JP) 2024-153175

(51) Int. Cl. G11C 5/06; G11C 13/00; H10B 63/00

(52) U.S. Cl. CPC G11C 5/063; G11C 13/0026; G11C 13/0028; G11C 13/004; G11C 13/0069; H10B 63/30

(57) ABSTRACT

According to one embodiment, a device includes: an array including a first interconnect extending in a first direction, second and third interconnects extending in a second direction, a first cell between the first and second interconnects, and a second cell between the first and third interconnects; a first switch circuit connected to the first interconnect; a second switch circuit connected to the second and third interconnects; first and second global interconnects connected between the second switch circuit and a first circuit, the second interconnect is disposed between the first switch circuit and the third interconnect in the first direction, the second interconnect is connected to the first global interconnect via the second switch circuit, the third interconnect is connected to the second global interconnect via the second switch circuit, and a length of the second global interconnect is shorter than a length of the first global interconnect.

### CROSS-REFERENCE TO RELATED APPLICATIONS

This application is based upon and claims the benefit of priority from Japanese Patent Application No. 2024-153175, filed Sep. 5, 2024, the entire contents of which are incorporated herein by reference.

### BACKGROUND

A memory device using a variable resistance element (for example, a magneto resistive effect element) as a memory element is known. In order to improve characteristics of a memory device, various techniques related to the memory device have been studied and developed.

### BRIEF DESCRIPTION OF DRAWINGS

FIG. 1 is a block diagram illustrating a configuration example of a memory device according to a first embodiment.

FIG. 2 is a circuit diagram illustrating a configuration example of a memory cell array of the memory device according to the first embodiment.

FIG. 3 is a bird's-eye view illustrating a configuration example of the memory cell array of the memory device according to the first embodiment.

FIG. 4 is a cross-sectional view illustrating a configuration example of the memory cell array of the memory device according to the first embodiment.

FIG. 5 is a cross-sectional view illustrating a configuration example of the memory cell array of the memory device according to the first embodiment.

FIG. 6 is a schematic diagram illustrating a configuration example of a memory cell of the memory device according to the first embodiment.

FIG. 7 is a plan view illustrating a configuration example of the memory device according to the first embodiment.

FIG. 8 is a cross-sectional view illustrating a configuration example of the memory device according to the first embodiment.

FIG. 9 is a cross-sectional view illustrating a configuration example of the memory device according to the first embodiment.

FIG. 10 is a plan view illustrating a configuration example of the memory device according to the first embodiment.

FIG. 11 is a cross-sectional view illustrating a configuration example of the memory device according to the first embodiment.

FIG. 12 is a cross-sectional view illustrating a configuration example of the memory device according to the first embodiment.

FIG. 13 is a plan view illustrating a configuration example of a memory device according to a second embodiment.

FIG. 14 is a plan view illustrating a configuration example of the memory device according to the second embodiment.

FIG. 15 is a plan view illustrating a configuration example of a memory device according to a third embodiment.

FIG. 16 is a plan view illustrating a configuration example of the memory device according to the third embodiment.

FIG. 17 is a diagram illustrating a modification of a memory device according to an embodiment.

FIG. 18 is a diagram illustrating a modification of a memory device according to an embodiment.

### DETAILED DESCRIPTION

In general, according to one embodiment, a memory device includes: a memory cell array that includes a first local interconnect extending in a first direction, a second local interconnect extending in a second direction intersecting with the first direction, a third local interconnect extending in the second direction, a first memory cell provided between the first local interconnect and the second local interconnect, and a second memory cell provided between the first local interconnect and the third local interconnect; a first switch circuit that is connected to the first local interconnect and provided on one end side of the memory cell array in the first direction; a second switch circuit that is connected to the second local interconnect and the third local interconnect and provided on one end side of the memory cell array in the second direction; a first circuit that executes a write operation or a read operation of the memory cell array; and a first global interconnect and a second global interconnect that are connected between the second switch circuit and the first circuit, wherein the second local interconnect is disposed between the first switch circuit and the third local interconnect in the first direction, the second local interconnect is connected to the first global interconnect via the second switch circuit, the third local interconnect is connected to the second global interconnect via the second switch circuit, and a length of the second global interconnect is shorter than a length of the first global interconnect.

Hereinafter, the present embodiment will be described in detail with reference to the drawings. In the following description, elements having the same function and configuration are denoted by the same reference numerals.

In each of the following embodiments, for a plurality of identical components (for example, circuits, interconnect, various voltages and signals, and the like), numbers/alphabetical characters may be added to the end of the reference numerals for differentiation. In a case where components having reference numerals with numbers/alphabetical characters for differentiation at the end are not necessarily distinguished from each other, a description (a reference number) is used in which the number/alphabetical character at the end is omitted.

### Embodiments

### (1) First Embodiment

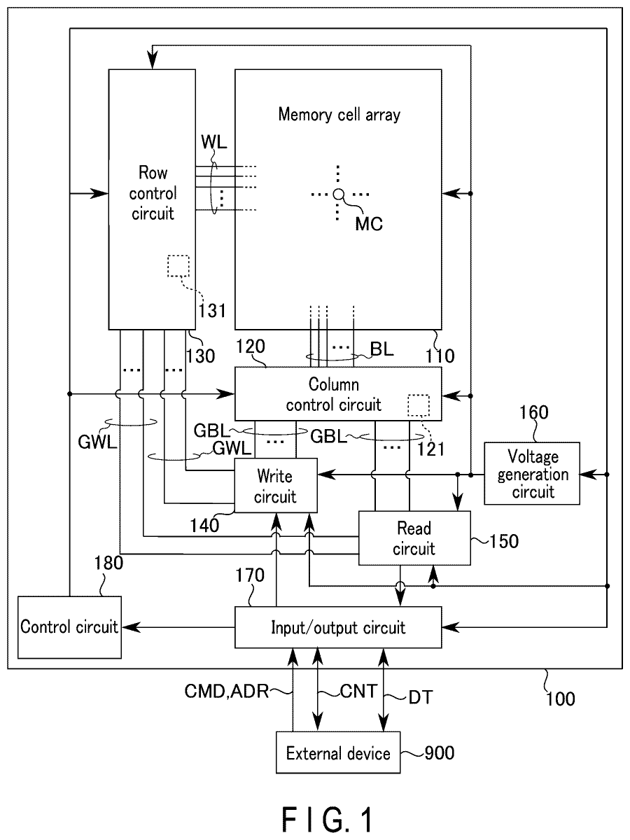

A memory device 100 according to the first embodiment will be described with reference to FIGS. 1 to 12.

### (a) Configuration Example

A configuration example of a memory device of the present embodiment will be described with reference to FIGS. 1 to 12.

### (a-1) Overall Configuration

FIG. 1 is a diagram illustrating a configuration example of the memory device 100 of the present embodiment.

As illustrated in FIG. 1, the memory device 100 of the present embodiment is connected to a device (hereinafter referred to as an external device) 900 external to the memory device 100.

The external device 900 sends a command CMD, an address ADR, and a control signal CNT to the memory device 100. Data DT is transferred between the memory device 100 and the external device 900. The external device 900 sends data to be written into the memory device 100 (hereinafter referred to as write data) to the memory device 100 during a write operation. The external device 900 receives data read from the memory device 100 (hereinafter referred to as read data) from the memory device 100 during a read operation.

The memory device 100 of the present embodiment includes a memory cell array 110, a column control circuit 120, a row control circuit 130, a write circuit 140, a read circuit 150, a voltage generation circuit 160, an input/output circuit 170, and a control circuit 180.

The memory cell array 110 includes a plurality of memory cells MC, a plurality of word lines WL, and a plurality of bit lines BL.

The plurality of memory cells MC are associated with a plurality of rows and a plurality of columns in the memory cell array 110. Each memory cell MC is connected to a corresponding one of the plurality of word lines WL. Each memory cell MC is connected to a corresponding one of the plurality of bit lines BL.

The column control circuit 120 controls columns of the memory cell array 110. The column control circuit 120 is connected to the memory cell array 110 via the bit line (local interconnect) BL. The column control circuit 120 receives a column address (or a decoding result of the column address) of the memory cell array 110 at the address ADR. The column control circuit 120 controls the plurality of bit lines BL based on the decoding result of the column address. Accordingly, the column control circuit 120 sets each of the plurality of bit lines BL (the plurality of columns) to a selected state or a non-selected state. Hereinafter, the bit line BL set to the selected state is referred to as a selected bit line BL, and the bit lines BL other than the selected bit line BL are referred to as unselected bit lines BL. The column control circuit 120 includes one or more column switch circuits 121. Each column switch circuit 121 controls connection between the selected bit line BL and a global interconnect to be described later.

The row control circuit 130 controls rows of the memory cell array 110. The row control circuit 130 is connected to the memory cell array 110 via the word line (local interconnect) WL. The row control circuit 130 receives a row address (or a decoding result of the row address) of the memory cell array 110 at the address ADR. The row control circuit 130 controls the plurality of word lines WL based on the decoding result of the row address. Accordingly, the row control circuit 130 sets each of the plurality of word lines WL (the plurality of rows) to the selected state or the non-selected state. Hereinafter, the word line WL set to the selected state is referred to as a selected word line WL, and the word lines WL other than the selected word line WL are referred to as unselected word lines WL. The row control circuit 130 includes one or more row switch circuits 131. Each row switch circuit 131 controls connection between the selected word line WL and a global interconnect to be described later.

The write circuit 140 writes data to the memory cell MC. The write circuit 140 is connected to the column control circuit 120 and the row control circuit 130 via global interconnects GBL and GWL. The write circuit 140 supplies voltage (or current) for writing data to each of the selected word line WL and the selected bit line BL via the global interconnects GBL and GWL. Accordingly, a certain write voltage (or write current) is supplied to the selected memory cell MC. The write circuit 140 can supply any one of a plurality of write voltages according to the write data to the selected memory cell MC. For example, each of the plurality of write voltages has a polarity (a bias direction) corresponding to the write data. For example, the write circuit 140 includes a write driver (not illustrated), a write sink (not illustrated), and the like.

The read circuit 150 reads data from the memory cell MC. The read circuit 150 is connected to the column control circuit 120 and the row control circuit 130 via global interconnects GBL and GWL. The read circuit 150 amplifies a signal output from the selected memory cell MC to the selected bit line BL. The read circuit 150 discriminates the data in the memory cell MC based on the amplified signal. For example, the read circuit 150 includes a preamplifier (not illustrated), a sense amplifier (not illustrated), a read driver (not illustrated), a read sink (not illustrated), and the like.

The voltage generation circuit 160 generates voltages for various operations of the memory cell array 110 using a power supply voltage provided from the external device 900. For example, the voltage generation circuit 160 generates various voltages used for the write operation. The voltage generation circuit 160 outputs the generated voltage to the write circuit 140. For example, the voltage generation circuit 160 generates various voltages used for the read operation. The voltage generation circuit 160 outputs the generated voltage to the read circuit 150.

The input/output circuit 170 functions as an interface circuit of various signals ADR, CMD, CNT, and DT between the memory device 100 and the external device 900. The input/output circuit 170 transfers the address ADR from the external device 900 to the control circuit 180. The input/output circuit 170 transfers the command CMD from the external device 900 to the control circuit 180. The input/output circuit 170 transfers various control signals CNT between the external device 900 and the control circuit 180. The input/output circuit 170 transfers the write data DT from the external device 900 to the write circuit 140. The input/output circuit 170 transfers the data DT from the read circuit 150 to the external device 900 as read data.

The control circuit (also referred to as a sequencer, a state machine, and an internal controller) 180 decodes the command CMD. The control circuit 180 controls operations of the column control circuit 120, the row control circuit 130, the write circuit 140, the read circuit 150, the voltage generation circuit 160, and the input/output circuit 170 in the memory device 100 based on a decoding result of the command CMD and the control signal CNT. The control circuit 180 decodes the address ADR. The control circuit 180 sends a decoding result of the address ADR to the column control circuit 120, the row control circuit 130, and the like. For example, the control circuit 180 includes a register circuit (not illustrated) that temporarily stores the command CMD and the address ADR. Note that, the register circuit, the circuit (a command decoder) for decoding the command CMD, and the circuit (an address decoder) for decoding the address ADR may be provided in the memory device 100 outside the control circuit 180.

### (a-2) Memory Cell Array

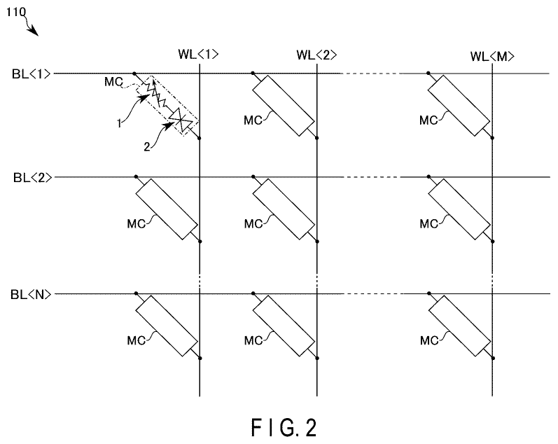

A configuration example of the memory cell array 110 in the memory device 100 of the present embodiment will be described with reference to FIGS. 2 to 5.

FIG. 2 is an equivalent circuit diagram illustrating a configuration example of the memory cell array 110 in the memory device 100 of the present embodiment.

As illustrated in FIG. 2, the plurality of memory cells MC are disposed in a matrix in the memory cell array 110. Each memory cell MC is connected to a corresponding one of the plurality of bit lines BL (BL<1>, BL<2>, . . . , BL<N>) and a corresponding one of the plurality of word lines WL (WL<1>, WL<2>, . . . , WL<M>). M and N are integers of 1 or more.

Each memory cell MC includes a memory element 1 and a switching element 2.

The memory element 1 is, for example, a variable resistance element. A resistance state of the memory element 1 is changed to any one of a plurality of resistance states (for example, a low resistance state and a high resistance state) depending on the supplied voltage (or current). The memory element 1 can store data by associating the resistance state of the element 1 with data (for example, “0” data and “1” data).

The switching element (or also referred to as a selector element or simply a selector) 2 functions as a selection element of the memory cell MC. The switching element 2 has a function of controlling supply of voltage (or current) to the memory element 1 when the data is written to the corresponding memory element 1 and when the data is read from the corresponding memory element 1.

For example, in a case where a certain voltage applied to a certain memory cell MC is lower than a threshold voltage of the switching element 2 in the memory cell MC, the switching element 2 is set to an OFF state (a high resistance state, a non-conductive state). In this case, the switching element 2 cuts off the voltage (or current) to the memory element 1. In a case where a certain voltage applied to a certain memory cell MC is equal to or higher than the threshold voltage of the switching element 2 in the memory cell MC, the switching element 2 is set to an ON state (a low resistance state, a conductive state). In this case, the switching element 2 supplies the voltage (or current) to the memory element 1.

The switching element 2 can switch whether to cause the current to flow in the memory cell MC according to the magnitude of the voltage applied to the memory cell MC regardless of the direction in which the current flows in the memory cell MC.

For example, the switching element 2 is a two-terminal type element. In the example of FIG. 2, one end of the switching element 2 is connected to the word line WL. The other end of the switching element 2 is connected to one end of the memory element 1. The other end of the memory element 1 is connected to the bit line BL.

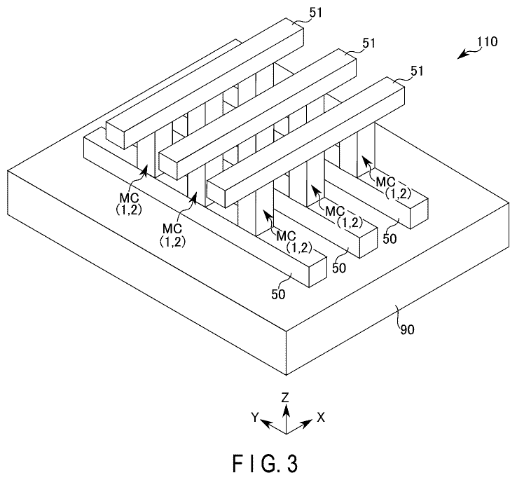

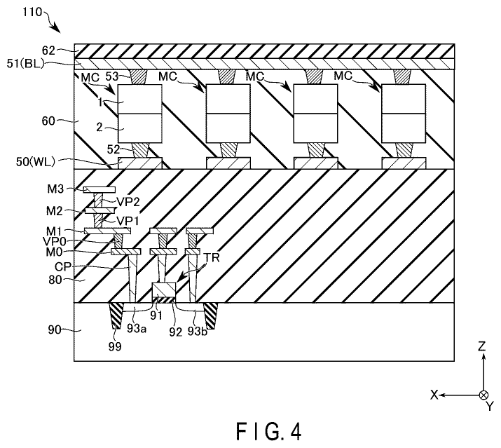

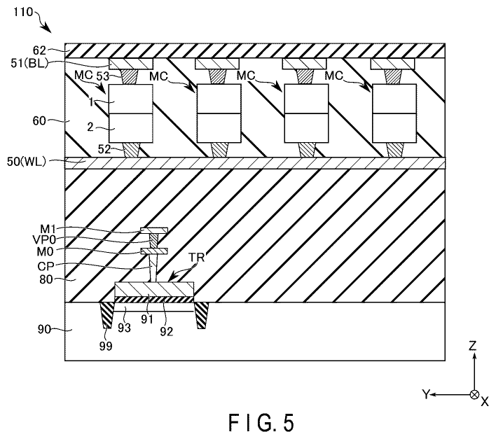

FIGS. 3 to 5 are diagrams for describing configuration examples of the memory cell array 110 in the memory device 100 of the present embodiment. FIG. 3 is a bird's-eye view for describing a configuration example of the memory cell array 110. FIG. 4 is a schematic cross-sectional view illustrating a cross-sectional structure along a first direction (axis) of the memory cell array 110. FIG. 5 is a schematic cross-sectional view illustrating a cross-sectional structure along a second direction (axis) of the memory cell array 110. In the examples of FIGS. 3 to 5, the first direction corresponds to an X direction, and the second direction corresponds to a Y direction.

As illustrated in FIGS. 3 to 5, the memory cell array 110 is provided above an upper surface of a substrate 90. The X direction is a direction parallel to the upper surface of the substrate 90. The Y direction is a direction that is parallel to the upper surface of the substrate 90 and intersects with the X direction.

Hereinafter, a plane parallel to the upper surface of the substrate 90 is referred to as an X-Y plane. A direction (an axis) perpendicular to the X-Y plane is a Z direction (a Z axis). A plane parallel to a plane defined by the X direction and the Z direction is referred to as an X-Z plane. A plane parallel to a plane defined by the Y direction and the Z direction is referred to as a Y-Z plane.

A plurality of interconnects (conductive layers) 50 are provided above the upper surface of the substrate 90 via an insulating layer 80 in the Z direction. The plurality of interconnects 50 are arranged along the X direction. Each interconnect 50 extends along the Y direction. The plurality of interconnects 50 function as, for example, the word lines WL.

A plurality of interconnects (conductive layers) 51 are provided above the plurality of interconnects 50 in the Z direction. The plurality of interconnect 51 are arranged along the Y direction. Each interconnect 51 extends along the X direction. The plurality of interconnects 51 function as, for example, the bit lines BL.

The plurality of memory cells MC are provided between the plurality of interconnects 50 and the plurality of interconnects 51. The plurality of memory cells MC are arranged in a matrix in the X-Y plane.

The plurality of memory cells MC arranged in the Y direction are provided above one interconnect 50. Two memory cells MC arranged in the Y direction are adjacent to each other with a predetermined interval. Each of the plurality of memory cells MC arranged in the Y direction is connected to a common interconnect 50 (the word line WL) via one corresponding contact 52. A plurality of contacts 52 are provided on one interconnect 50.

The plurality of memory cells MC arranged in the X direction are provided below one interconnect 51. Two memory cells MC arranged in the X direction are adjacent to each other with a predetermined interval. Each of the plurality of memory cells MC arranged in the X direction is connected to a common interconnect 51 (the bit line BL) via one corresponding contact 53. A plurality of contacts 53 are provided below one interconnect 51.

For example, in a case where the memory cell array 110 has the circuit configuration of FIG. 2, the switching element 2 is provided below the memory element 1 in the Z direction. The switching element 2 is provided between the memory element 1 and the interconnect 50 (the word line WL). The memory element 1 is provided between the interconnect 51 (the bit line BL) and the switching element 2.

In this way, each memory cell MC is a stack of the memory element 1 and the switching element 2. With this memory cell MC, the memory cell array 110 has a stacked configuration.

The memory cell MC may have a tapered cross-sectional shape according to a process (for example, an etching method) used to form the memory cell array 110.

An insulating layer 60 is provided above the substrate 90. The insulating layer 60 covers the memory cell MC, the interconnects 50 and 51, and the contacts 52 and 53. An insulating layer 62 is provided on the insulating layer 60 and the interconnect 51.

FIGS. 4 and 5 illustrate examples in which the insulating layer 80 is provided between the plurality of interconnects 50 and the substrate 90. In a case where the substrate 90 is a semiconductor substrate, one or more field effect transistors TR may be provided on a semiconductor region of the upper surface of the substrate 90. The field effect transistor TR is covered with the insulating layer 80. The field effect transistor TR is provided on the semiconductor region surrounded by an element isolation insulating layer 99. The field effect transistor TR includes a gate electrode 91, a gate insulating film 92, and source/drain layers 93a and 93b. The source/drain layers (diffusion layers) 93a and 93b are provided in the semiconductor region. The gate electrode 91 is disposed on the semiconductor region between the source/drain layers 93a and 93b via the gate insulating film 92. Contact plugs CP are provided on the gate electrode 91 and the source/drain layers 93a and 93b.

A plurality of conductive layers M0, M1, M2, and M3 having a multilayer interconnect structure, the contact plugs CP, and via plugs VP (VP0, VP1, VP2, and VP3) are provided in the insulating layer 80. The field effect transistor TR on the substrate 90 is a component of circuits such as the column control circuit 120 and the row control circuit 130. The field effect transistor TR is connected to the memory cell array 110 via the conductive layers M0, M1, M2, and M3, the contact plugs CP, and the via plugs VP0, VP1, VP2, and VP3 in the insulating layer 80. In this way, a circuit for controlling the operation of the memory cell array 110 can be provided below the memory cell array 110 in the Z direction.

The circuit configuration and structure of the stacked memory cell array 110 are not limited to the examples illustrated in FIGS. 2 to 5. The circuit configuration and structure of the memory cell array 110 can be appropriately modified according to a connection relationship between the memory element 1 and the switching element 2 to the bit line BL and the word line WL. For example, the structure of the memory cell array 110 having the circuit configuration of FIG. 2 is not limited to the examples of FIGS. 3 to 5. For example, the switching element 2 may be provided above the memory element 1 in the Z direction. In this case, the interconnect 50 is used as the bit line BL, and the interconnect 51 is used as the word line WL.

### (a-3) Memory Cell

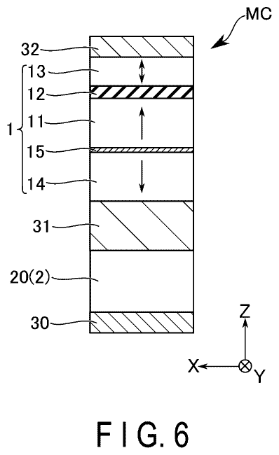

FIG. 6 is a cross-sectional view illustrating a configuration example of the memory cell MC in the memory device 100 of the present embodiment.

As illustrated in FIG. 6, in the memory cell MC which is the stack, the memory element 1 and the switching element 2 are arranged in the Z direction. In this example, the memory element 1 is provided on the switching element 2 in the Z direction.

For example, the variable resistance element as the memory element 1 is a magnetoresistive effect element. In this case, the memory device 100 of the present embodiment is a magnetic memory such as a magnetoresistive random access memory (MRAM).

### Configuration Example of Magnetoresistive Effect Element

For example, a magnetoresistive effect element 1 includes at least two magnetic layers 11 and 13 and a non-magnetic layer 12. The non-magnetic layer 12 is provided between the two magnetic layers 11 and 13 in the Z direction. In the example of FIG. 6, a plurality of layers 11,12, and 13 are arranged in the Z direction in an order of the magnetic layer 11, the non-magnetic layer 12, and the magnetic layer 13 from a side of the word line WL (the interconnect 50) toward a side of the bit line BL (the interconnect 51).

The two magnetic layers 11 and 13 and the non-magnetic layer 12 form a magnetic tunnel junction. Hereinafter, the magnetoresistive effect element 1 including the magnetic tunnel junction is referred to as a magnetic tunnel junction (MTJ) element 1. The non-magnetic layer 12 in the MTJ element 1 is referred to as a tunnel barrier layer.

The magnetic layers 11 and 13 are ferromagnetic layers including, for example, cobalt (Co), iron (Fe), and/or boron (B). The magnetic layers 11 and 13 may be single layer films (for example, alloy films) or multilayer films (for example, artificial lattice films). The tunnel barrier layer 12 is, for example, an insulating layer including magnesium oxide. The tunnel barrier layer 12 may be a single layer film or a multilayer film.

In a case where the MTJ element 1 is a perpendicular magnetization type magnetoresistive effect element, each of the magnetic layers 11 and 13 has perpendicular magnetic anisotropy. The direction of an easy magnetization axis of each of the magnetic layers 11 and 13 is perpendicular to a layer surface (a film surface) of a respective one of the magnetic layers 11 and 13. Each of the magnetic layers 11 and 13 has magnetization perpendicular to the layer surface of the respective one of the magnetic layers 11 and 13. The direction of magnetization of each of the magnetic layers 11 and 13 is parallel to an arrangement direction (the Z direction) of the magnetic layers 11 and 13.

Of the two magnetic layers 11 and 13, one magnetic layer has a variable magnetization direction, and the other magnetic layer has an invariable magnetization direction. The MTJ element 1 may have a plurality of resistance states (resistance values) according to a relative relationship (a magnetization arrangement) between the magnetization direction of one magnetic layer and the magnetization direction of the other magnetic layer.

For example, the magnetization direction of the magnetic layer 13 is variable. The magnetization direction of the magnetic layer 11 is invariable (in a fixed state). Hereinafter, the magnetic layer 13 having a variable magnetization direction is referred to as a storage layer. Hereinafter, the magnetic layer 11 having an invariable magnetization direction (in a fixed state) is referred to as a reference layer. Note that, the storage layer 13 may also be referred to as a free layer, a magnetization free layer, or a magnetization variable layer. The reference layer 11 may also be referred to as a pin layer, a pinned layer, a magnetization invariant layer, or a magnetization fixed layer.

In the present embodiment, “the magnetization direction of the reference layer (the magnetic layer) is invariable” or “the magnetization direction of the reference layer (the magnetic layer) is in a fixed state” means that, in a case where a current or a voltage for changing the magnetization direction of the storage layer 13 is supplied to the MTJ element 1, the magnetization direction of the reference layer 11 does not change according to the supplied current or voltage before and after the supply of the current/voltage.

In a case where the magnetization direction of the storage layer 13 is the same as the magnetization direction of the reference layer 11 (in a case where a magnetization arrangement state of the MTJ element 1 is a parallel arrangement state), the resistance state of the MTJ element 1 is a first resistance state. In a case where the magnetization direction of the storage layer 13 is different from the magnetization direction of the reference layer 11 (in a case where the magnetization arrangement state of the MTJ element 1 is an antiparallel arrangement state), the resistance state of the MTJ element 1 is a second resistance state different from the first resistance state. The resistance value of the MTJ element 1 in the second resistance state (the antiparallel arrangement state) is higher than the resistance value of the MTJ element 1 in the first resistance state (the parallel arrangement state).

Hereinafter, for the magnetization arrangement state of the MTJ element 1, the parallel arrangement state is also denoted as a P state, and the antiparallel arrangement state is also denoted as an AP state.

For example, the MTJ element 1 is connected to two electrodes 31 and 32. The magnetic layers 11 and 13 and the tunnel barrier layer 12 are provided between the two electrodes 31 and 32 in the Z direction. The reference layer 11 is provided between the electrode (referred to as an intermediate electrode) 31 and the tunnel barrier layer 12. The storage layer 13 is provided between the electrode (referred to as an upper electrode) 32 and the tunnel barrier layer 12.

For example, a shift cancelling layer 14 may be provided in the MTJ element 1. In this case, the shift cancelling layer 14 is provided between the reference layer 11 and the intermediate electrode 31. The shift cancelling layer 14 is a magnetic layer for mitigating an influence of a stray field of the reference layer 11. In a case where the MTJ element 1 includes the shift cancelling layer 14, a non-magnetic layer 15 is provided between the shift cancelling layer 14 and the reference layer 11. The non-magnetic layer 15 is, for example, a metal layer such as a ruthenium (Ru) layer. The shift cancelling layer 14 is antiferromagnetically coupled to the reference layer 11 via the non-magnetic layer 15. Accordingly, the stack including the reference layer 11 and the shift cancelling layer 14 forms a synthetic antiferromagnetic (SAF) structure. In the SAF structure, the magnetization direction of the shift cancelling layer 14 is opposite to the magnetization direction of the reference layer 11. With the SAF structure, the magnetization direction of the reference layer 11 can be more stably fixed. Note that, a set of the two magnetic layers 11 and 14 and the non-magnetic layer 15 forming the SAF structure may be referred to as a reference layer.

For example, the MTJ element 1 may include at least one of a base layer (not illustrated) and a capping layer (not illustrated). The base layer is provided between the magnetic layer (here, the shift cancelling layer) 14 and the intermediate electrode 31. The base layer is a non-magnetic layer (for example, a conductive layer). The base layer is a layer for improving the characteristics (for example, crystallinity and/or magnetic properties) of the magnetic layer 14 in contact with the base layer. The capping layer is provided between the magnetic layer (here, the storage layer) 13 and the upper electrode 32.

The capping layer is a non-magnetic layer (for example, a conductive layer). The capping layer is a layer for improving the characteristics (for example, crystallinity and/or magnetic properties) of the magnetic layer 13 in contact with the capping layer. Note that, each of the base layer and the capping layer may be regarded as a component of the electrodes 31 and 32.

### Configuration Example of Switching Element

As illustrated in FIG. 6, in a case where the switching element 2 is a two-terminal type element, the switching element 2 includes at least one variable resistance layer (also referred to as a switching layer or a selector layer) 20. The variable resistance layer 20 is provided between two electrodes 30 and 31 in the Z direction. The variable resistance layer 20 can be in a plurality of resistance states.

The electrode (referred to as a lower electrode) 30 is provided below the variable resistance layer 20 in the Z direction, and the intermediate electrode 31 is provided above the variable resistance layer 20 in the Z direction. For example, the lower electrode 30 is provided between the interconnect 50 and the variable resistance layer 20. The electrode 31 is provided between the variable resistance layer 20 and the MTJ element 1.

The variable resistance layer 20 is connected to the interconnect 50 via the lower electrode 30 and the contact 52. The variable resistance layer 20 is connected to the MTJ element 1 via the intermediate electrode 31.

The resistance state of the variable resistance layer 20 becomes a high resistance state (a non-conduction state) or a low resistance state (a conduction state) according to the voltage applied to the switching element 2 (the memory cell MC). In a case where the resistance state of the variable resistance layer 20 is the high resistance state, the switching element 2 is turned off. In a case where the resistance state of the variable resistance layer 20 is the low resistance state, the switching element 2 is turned on.

In a case where the memory cell MC is set to the selected state, the switching element 2 is turned on, so that the resistance state of the variable resistance layer 20 is the low resistance state. In a case where the memory cell MC is set to the non-selected state, the switching element 2 is turned off, so that the resistance state of the variable resistance layer 20 is the high resistance state.

Note that, according to a material of the variable resistance layer 20, a change in the resistance state of the variable resistance layer 20 may also depend on the current (for example, the magnitude of the current) flowing in the switching element 2 (the memory cell MC).

For example, the lower electrode 30 and the upper electrode 32 are conductive layers made of titanium (Ti), tungsten (W), titanium nitride (TiN), tungsten nitride (WN), or the like. The intermediate electrode 31 is a conductive layer made of carbon (C) or carbon nitride (CN).

The memory cell array 110 having the structures of FIGS. 3 to 6 can be formed using well-known techniques.

### (a-4) Configurations of Global Word Line and Global Bit Line

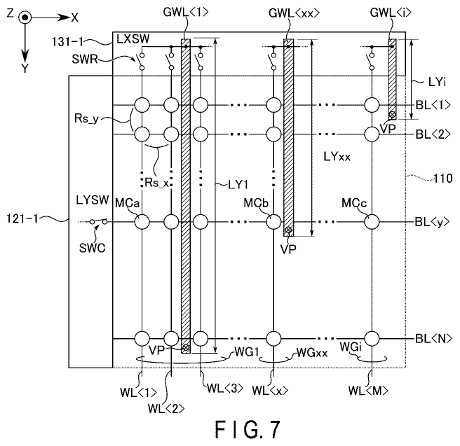

FIGS. 7 to 12 are diagrams for describing configurations of the global interconnect in the memory cell array 110 of an MRAM 100 of the present embodiment.

FIG. 7 is a plan view illustrating a configuration example of a global word line in the MRAM 100 of the present embodiment.

As illustrated in FIG. 7, the memory cell array 110 has a quadrangular layout when viewed from the Z direction.

M word lines WL<1>, WL<2>, . . . , WL<x>,. WL<M−1>, and WL<M> are arranged in the X direction with predetermined intervals within the memory cell array 110. N bit lines BL<1>, BL<2>, . . . , BL<y>, . . . , BL<N−1>, BL<N> are arranged in the Y direction with predetermined intervals within the memory cell array 110. The bit lines BL are disposed above the word lines WL in the Z direction. Lengths of the plurality of word lines WL are the same. Lengths of the plurality of bit lines BL are the same.

For example, the memory cell MC is disposed at coordinates indicated by (x, y) in the memory cell array 110. The memory cell MC is provided at a position where the word line WL<x> and the bit line BL<y> intersect with each other. x is an integer of 1 or more and M or less. y is an integer of 1 or more and N or less.

For example, a value of “M” is equal to a value of “N”. The interval between the memory cells MC in the X direction is equal to the interval between the memory cells MC in the Y direction. The memory cell array 110 has a square layout (a planar structure) when viewed from the Z direction.

In a case where the plurality of memory cells MC are arranged at predetermined intervals in the X direction, interconnect resistance between two memory cells MC adjacent to each other in the X direction has a resistance value of “Rs_x”. If the address of the word line WL changes by one, the interconnect resistance applied to the memory cell MC varies by “Rs_x”. In a case where the plurality of memory cells MC are arranged at predetermined intervals in the Y direction, interconnect resistance between two memory cells MC adjacent to each other in the Y direction has a resistance value of “Rs_y”. If the address of the bit line BL changes by one, the interconnect resistance applied to the memory cell MC varies by “Rs_y”.

For example, in the present embodiment, a value of “Rs_x” is equal to a value of “Rs_y”. Hereinafter, the resistance between the memory cells MC is also denoted as “Rs”.

As illustrated in FIG. 7, in the MRAM of the present embodiment, the row control circuit 130 includes a row switch circuit 131-1. The row switch circuit 131-1 is provided on one end side of the memory cell array 110 in the Y direction. Hereinafter, in the memory cell array 110, a region on a side close to the row switch circuit 131-1 is referred to as a near region (a near side), and a region on a side far from the row switch circuit 131-1 is referred to as a far region (a far side).

The row switch circuit 131-1 is connected to the plurality of word lines WL. The row switch circuit 131-1 is connected to a plurality of global word lines GWL (GWL<1>, GWL<xx>, and GWL<i>). Each of the global word lines GWL is connected to the write circuit 140 and the read circuit 150.

The row switch circuit 131-1 includes a plurality of row switches SWR. The row switches SWR are, for example, field effect transistors TR. One end of each of the row switches SWR is electrically connected to one corresponding word line WL of the plurality of word lines WL. The other end of each of the row switches SWR is electrically connected to one corresponding global word line GWL of the plurality of global word lines GWL.

In the row switch circuit 131-1, each of the row switches SWR is set to the ON state or the OFF state according to the supplied address ADR. In response to on/off of the plurality of row switches SWR in the row switch circuit 131-1, one word line WL is electrically connected to the global word line GWL via the row switch SWR in the ON state.

A distance between the memory cell MC and a column switch SWC changes corresponding to coordinates in the X direction (row) of the memory cell MC in the memory cell array 110.

As a result, in operations of the MRAM 100, the magnitude of interconnect resistance of the bit line BL applied to the memory cell MC in the memory cell array 110 changes corresponding to the coordinates in the X direction (row) of the memory cell MC.

In the present embodiment, the plurality of global word lines GWL have lengths different from each other.

Accordingly, the MRAM 100 of the present embodiment alleviates an influence caused by a difference in the interconnect resistance of the bit lines BL corresponding to the coordinates of the memory cell MC.

A plurality of memory cells MCa, MCb, and MCc are connected to a certain bit line BL<y>.

The memory cell MCa is connected to the word line WL<1>. The memory cell MCb is connected to the word line WL<x>. The memory cell MCc is connected to the word line WL<M>.

Coordinates of the memory cells MCa, MCb, and MCc in the Y direction (column) are the same. A distance between each of the memory cells MCa, MCb, and MCc and a corresponding one of the row switches SWR is the same.

Therefore, the interconnect resistance (hereinafter, referred to as word line resistance) of the word lines WL respectively applied to the memory cells MCa, MCb, and MCc has the same magnitude (y×Rs_y) as another.

Coordinates of the memory cells MCa, MCb, and MCc in the X direction (row) are different. Therefore, distances between each of the memory cells MCa, MCb, and MCc and the column switch circuit 121 (the column switch SWC) are different from each other. As a result, the interconnect resistance (hereinafter, referred to as bit line resistance) of the bit lines BL respectively applied to the memory cells MCa, MCb, and MCc is different from another. Bit line resistance between the memory cell MCa on the near side and the column switch SWC is “1×Rs_x”. Bit line resistance between the memory cell MCb and the column switch SWC is “x×Rs_x”. Bit line resistance between the memory cell MCc on the far side and the column switch SWC is “M×Rs_x”. The bit line resistance (1×Rs_x) between the memory cell MCa and the column switch SWC is lower than the bit line resistance x×Rs_x and the bit line resistance M×Rs_x. The bit line resistance x×Rs_x between the memory cell MCb and the column switch SWC is higher than the bit line resistance 1×Rs_x and lower than the bit line resistance M×Rs_x. The bit line resistance M×Rs_x between the memory cell MCc and the column switch SWC is higher than the bit line resistance 1×Rs_x and the bit line resistance x×Rs_x.

In this way, for the plurality of memory cells MC connected to a common bit line BL, the magnitude of the bit line resistance applied to the selected memory cell MC changes corresponding to the X coordinate of the memory cell MC.

Each of the global word lines GWL is associated with a corresponding set (hereinafter, referred to as a word line group) WG1, WGxx, or WGi of the plurality of word lines. Each of the word line groups WG1, WGxx, and WGi includes a predetermined number of word lines WL.

The global word line GWL<1> is associated with the word line group WG1 including the word line WL<1> in a region of the memory cell array 110 in the X direction on a side on which a column switch circuit 121-1 is disposed (one end side of the memory cell array 110 in the X direction). The global word line GWL<1> is connected to the plurality of word lines WL in the word line group WG1 via the plurality of row switches SWR.

The global word line GWL<i> is associated with the word line group WGi including the word line <M> in a region of the memory cell array 110 in the X direction on an opposite side (the other end side of the memory cell array 110 in the X direction) to the side on which the column switch circuit 121-1 is disposed. The global word line GWL<i> is connected to the plurality of word lines WL in the word line group WGi via the plurality of row switches SWR.

The global word line GWL<xx> is associated with the word line group WGxx including the word line WL<x> in a region (a central region) between one end side and the other end side of the memory cell array 110 in the X direction. The global word line GWL<xx> is connected to the plurality of word lines WL in the word line group WGxx via the plurality of row switches SWR.

As described above, the global word lines GWL and the global bit lines GBL are provided between the substrate 90 and the memory cell array 110 in the Z direction. The plurality of global word lines GWL are provided in the multilayer interconnect structure on the substrate 90.

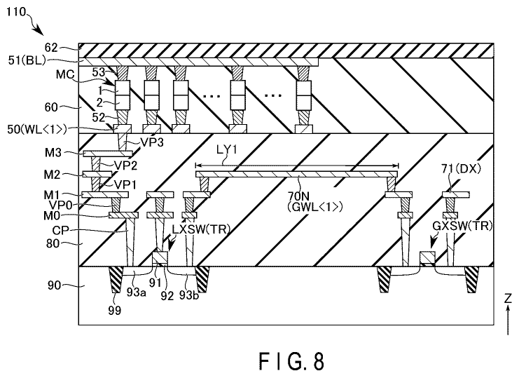

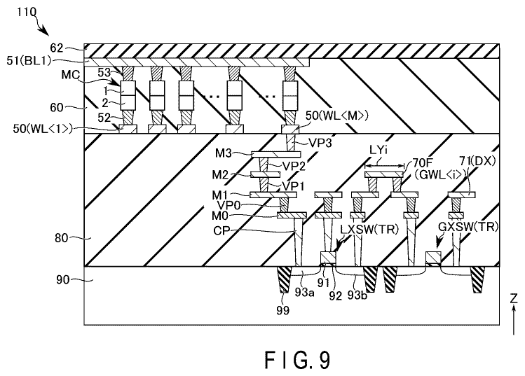

FIGS. 8 and 9 are cross-sectional views schematically illustrating structural examples of the plurality of global word lines GWL in the MRAM 100 of the present embodiment.

FIG. 8 illustrates a structure of the global word line GWL<1> of the plurality of global word lines GWL. FIG. 9 illustrates a structure of the global word line GWL<i> of the plurality of global word lines GWL.

As illustrated in FIGS. 8 and 9, the row switch SWR (the field effect transistor TR) is provided on the semiconductor substrate 90. One end of the row switch SWR is connected to the word line WL via the plurality of conductive layers M0, M1, M2, and M3, the contact plugs CP, and the via plugs VP0, VP1, VP2, and VP3. The other end of the row switch SWR is connected to one end of the global word line GWL via the plurality of conductive layers M0 and M1, the contact plugs CP, and the via plugs VP0 and VP1.

The field effect transistor TR of the global switch GXSW is provided on the semiconductor substrate 90. One end of the global switch GXSW is connected to the other end of the global word line GWL. The other end of the global switch GXSW is connected to an interconnect DX via the plurality of conductive layers M0 and 71, the contact plugs CP, and the via plug VP0. The interconnect DX is connected to the write circuit 140 or the read circuit 150.

The plurality of global word lines GWL are provided below the memory cell array 110 in the Z direction. The global word line GWL is connected between the transistor TR of the row switch SWR and the transistor TR of the global switch GXSW. For example, the global word line GWL is provided in a hierarchy (an interconnect level) of the conductive layer M2. As illustrated in FIG. 8, the global word line GWL<1> includes a conductive layer 70N. As illustrated in FIG. 9, the global word line GWL<i> includes a conductive layer 70F.

For example, a cross-sectional area SGWL of the global word line GWL is larger than a cross-sectional area SWL of the word line WL and a cross-sectional area SBL of the bit line BL. Therefore, a resistivity of a material used in the global word line GWL is desirably higher than resistivity of a material used in the bit line BL.

Materials of the conductive layers 70N and 70F of the global word line GWL are different from materials of the conductive layers M0, M1, M2, and M3. The materials of the conductive layers 70N and 70F are desirably materials having relatively high resistivities. For example, the materials of the conductive layers 70N and 70F are any one selected from oxides of tantalum (Ta), titanium (Ti), and an oxide of tungsten (W), a nitride of tungsten, an oxide of silicon (Si), and a nitride of silicon. The materials of the conductive layers M0, M1, M2, and M3 are, for example, copper (Cu).

In order to adjust the length of the global word line GWL, a position of the row switch SWR and a position of the global switch GXSW on the semiconductor substrate 90 can be appropriately changed.

A width (dimensions in the X direction) of the global word line GWL is larger than a width (dimensions in the X direction) of the word line WL.

As illustrated in FIGS. 7 to 9, the global word lines GWL mainly extend in the Y direction.

The global word line GWL<1> has a length (an interconnect length) LY1. The global word line GWL<xx> has a length LYxx. The global word line GWL<i> has a length LYi. The length LY1 is longer than the lengths LYxx and LYi. The length LYxx is shorter than the length LY1 and longer than the length LYi. The length LYi is shorter than the lengths LY1 and LYxx. For example, the length LY1 is equal to dimensions of the memory cell array 110 in the Y direction (a length of a set of the memory cells arranged in the Y direction).

In this way, the memory cell MCa, which is closer to the column switch circuit 121-1, is connected to the global word line GWL<1> having a long interconnect length, and the memory cell MCc, which is farther from the column switch circuit 121-1, is connected to the global word line GWL<i> having a short interconnect length.

A resistance value of the interconnect is proportional to the length. Therefore, interconnect resistance of the global word line GWL<1> is higher than interconnect resistance of the global word line GWL<xx> and interconnect resistance of the global word line GWL<i>. The interconnect resistance of the global word line GWL<xx> is lower than the interconnect resistance of the global word line GWL<1> and higher than the interconnect resistance of the global word line GWL<i>. The interconnect resistance of the global word line GWL<i> is lower than the interconnect resistance of the global word line GWL<1> and the interconnect resistance of the global word line GWL<xx>.

In a case where a resistance value per unit length of the global word line GWL is indicated by “RGWL”, the interconnect resistance of the global word line GWL<1> is “LY1×RGWL”, the interconnect resistance of the global word line GWL<xx> is “LYxx×RGWL”, and the interconnect resistance of the global word line GWL<i> is “LYi×RGWL”.

For example, a difference between bit line resistance of the memory cell MCa and bit line resistance of the memory cell MCc is “(M−1)×Rs_x”. Further, a difference between a resistance value of the global word line GWL<1> and a resistance value of the global word line GWL<i> is “(LY1−LYi)×RGWL”.

In a case of offsetting the difference in bit line resistance, the magnitude of (LY1−LYi)×RGWL is desirably close to the magnitude of (M−1)×Rs_x. In a case where the magnitude of (LY1−LYi)×RGWL is equal to the magnitude of (M−1)×Rs_x, an influence of the difference in bit line resistance is substantially 0.

In a case where a unit length Ly of the global word line GWL is indicated to be the same as a pitch between the memory cells MC, “N×RGWL×Ly” is desirably equal to “M×Rs_x”. In a case where N is equal to M, the resistivity per unit length of the global word line GWL may be equal to the resistivity per unit length of the bit line.

As described above, the difference in bit line resistance corresponding to the coordinates of the memory cell MC in the X direction is reduced by the difference in interconnect resistance of the global word lines GWL.

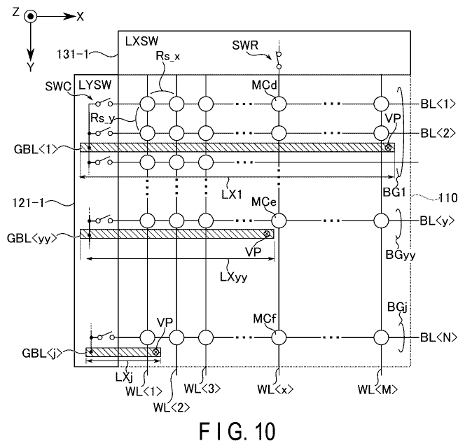

FIG. 10 is a plan view illustrating a configuration example of the global bit line GBL in the MRAM 100 of the present embodiment.

In the MRAM 100, the column control circuit 120 includes the column switch circuit 121-1. The column switch circuit 121-1 is provided on one end side of the memory cell array 110 in the X direction. Hereinafter, in the memory cell array 110, a region on a side close to the column switch circuit 121-1 is referred to as a near region (a near side), and a region on a side far from the column switch circuit 121-1 is referred to as a far region (a far side).

The column switch circuit 121-1 is connected to the plurality of bit lines BL. The column switch circuit 121-1 is connected to the plurality of global bit lines GBL(GBL<1>, GBL<yy>, and GBL<j>). Each of the global bit lines GBL is connected to the write circuit 140 and the read circuit 150.

The column switch circuit 121-1 includes the plurality of column switches SWC. The column switches SWC are, for example, field effect transistors TR. One end of each of the column switches SWC is electrically connected to one corresponding bit line BL of the plurality of bit lines BL. The other end of each of the column switches SWC is electrically connected to a corresponding one of the plurality of global bit lines GBL.

In the column switch circuit 121-1, each of the column switches SWC is set to the ON state or the OFF state according to the supplied address ADR. In response to on/off of the plurality of column switches SWC in the column switch circuit 121-1, one bit line BL is electrically connected to a corresponding global bit line GBL via the column switch SWC in the ON state.

A distance between the memory cell MC and the row switch SWR changes corresponding to the coordinates in the Y direction (column) of the memory cell MC in the memory cell array 110.

As a result, during the operations of the MRAM 100, the magnitude of interconnect resistance of the word line WL applied to the memory cell MC in the memory cell array 110 changes corresponding to the coordinates in the Y direction of the memory cell MC.

In the present embodiment, the plurality of global bit lines GBL have lengths different from each other. Accordingly, the MRAM 100 of the present embodiment alleviates an influence caused by the difference in the interconnect resistance of the word lines WL corresponding to the coordinates of the memory cell MC.

As illustrated in FIG. 10, a plurality of memory cells MCd, MCe, and MCf are connected to a certain word line WL<x>.

The memory cell MCd is connected to the bit line BL<1>. The memory cell MCe is connected to the bit line BL<y>. The memory cell MCf is connected to the bit line BL<N>.

The coordinates of the memory cells MCd, MCe, and MCf in the X direction (row) are the same. Therefore, the bit line resistance applied to each of the memory cells MCd, MCe, and MCf is of the same magnitude (x×Rs_x).

The coordinates of the memory cells MCd, MCe, and MCf in the Y direction are different. Therefore, distances between each of the memory cells MCd, MCe, and MCf and the row switch circuit 131 (the row switch SWR) are different from each other. As a result, the word line resistance applied to each of the memory cells MCd, MCe, and MCf is different from another. The word line resistance between the memory cell MCd on the near side and the row switch SWR is “1×Rs_y”. The word line resistance between the memory cell MCe and the row switch SWR is “y×Rs_y”. The word line resistance between the memory cell MCf on the far side and the row switch SWR is “N×Rs_y”. The word line resistance 1×Rs_y between the memory cell MCd and the row switch SWR is lower than the word line resistance y×Rs_y and N×Rs_y. The word line resistance y×Rs_y between the memory cell MCe and the row switch SWR is higher than the word line resistance 1×Rs_y and lower than the word line resistance N×Rs_y. The word line resistance N×Rs_y between the memory cell MCf and the row switch SWR is higher than the word line resistance 1×Rs_y and the word line resistance N×Rs_y.

In this way, for the plurality of memory cells MC connected to a common word line WL, the magnitude of the word line resistance applied to the selected memory cell MC changes corresponding to the Y coordinate of the memory cell MC.

Note that the resistivity per unit length (Ω/nm) of the global word line GWL is desirably about the same as the resistivity per unit length (Ω/nm) of the bit line BL. As illustrated in FIG. 10, each of global bit lines GBL is associated with a corresponding set (hereinafter, referred to as a bit line group) BG1, BGyy, or BGj of the plurality of bit lines. Each of the bit line groups BG1, BGyy, and BGj includes a predetermined number of the bit lines BL.

The global bit line GBL<1> is associated with the bit line group BG1 including a bit line BL1 in a region of the memory cell array 110 in the Y direction on a side on which the row switch circuit 131-1 is disposed (one end side of the memory cell array 110 in the Y direction). The global bit line GBL<1> is connected to the plurality of bit lines BL in the bit line group BG1 via each of the plurality of column switches SWC.

The global bit line GBL<j> is associated with the bit line group BGj including the bit line BL<N> in a region of the memory cell array 110 in the Y direction on an opposite side (the other end side of the memory cell array 110 in the Y direction) to the side on which the row switch circuit 131-1 is disposed. The global bit line GBL<j> is connected to the plurality of bit lines BL in the bit line group BGj via each of the plurality of column switches SWC.

The global bit line GBL<yy> is associated with the bit line group BGyy including the bit line BL<y> in a region (a central region) between one end side and the other end side of the memory cell array 110 in the Y direction. The global bit line GBL<yy> is connected to the plurality of bit lines BL in the bit line group BGyy via each of the plurality of column switches SWC.

As described above, the global bit lines GBL are provided between the substrate 90 and the memory cell array 110 in the Z direction. The plurality of global bit lines GBL are provided in the multilayer interconnect structure on the substrate 90.

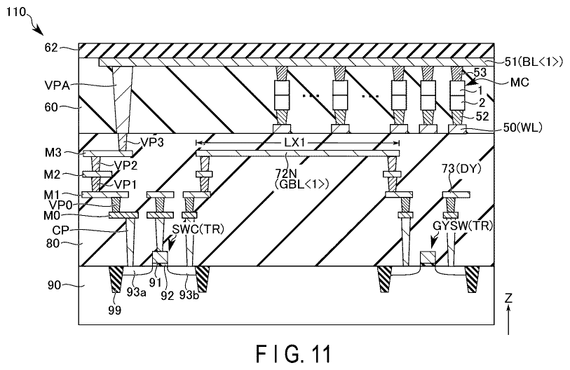

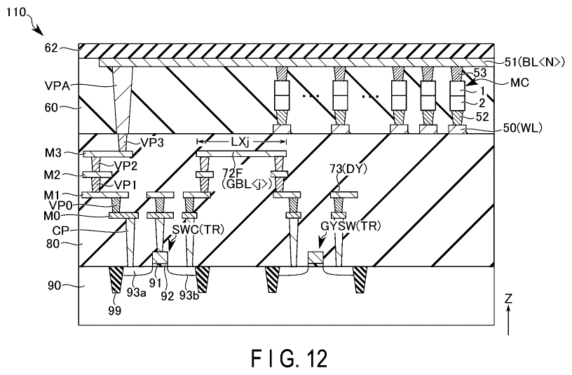

FIGS. 11 and 12 are cross-sectional views schematically illustrating structural examples of the plurality of global bit lines GBL in the MRAM 100 of the present embodiment.

FIG. 11 illustrates a structure of the global bit line GBL<1> of the plurality of global bit lines GBL. FIG. 12 illustrates a structure of the global bit line GBL<j> of the plurality of global bit lines GBL.

As illustrated in FIGS. 11 and 12, the column switch SWC (the field effect transistor TR) is provided on the semiconductor substrate 90. One end of the column switch SWC is connected to the bit line BL via the plurality of conductive layers M0, M1, M2, and M3, the contact plugs CP, and the via plugs VP0, VP1, VP2, VP3, and VPA. The other end of the column switch SWC is connected to one end of the global bit line GBL via the plurality of conductive layers M0, M1, and M2, the contact plugs CP, and the via plugs VP0, VP1, and VP2.

The field effect transistor TR of a global switch GYSW is provided on the semiconductor substrate 90. One end of the global switch GYSW is connected to the other end of the global bit line GBL. The other end of the global switch GYSW is connected to an interconnect DY via a plurality of conductive layers M0 and 73, the contact plugs CP, and the via plug VP0. The interconnect DY is connected to the write circuit 140 or the read circuit 150.

The plurality of global bit lines GBL are provided below the memory cell array 110 in the Z direction. The global bit line GBL is connected between the transistor TR of the column switch SWC and the transistor TR of the global switch GYSW. In the multilayer interconnect structure, a hierarchy in which the global bit line GBL is provided is different from the hierarchy in which the global word line GWL is provided. For example, the global bit line GBL is provided in a hierarchy of the conductive layer M3. Note that the hierarchy in which the global bit line GBL is provided may be a hierarchy (for example, a hierarchy of the conductive layer M0 or a hierarchy of the conductive layer M1) lower than the hierarchy in which the global word line GWL is provided. The hierarchy in which the global bit line GBL is provided may be the same as the hierarchy in which the global word line GWL is provided.

As illustrated in FIG. 11, the global bit line GBL<1> includes a conductive layer 72N. As illustrated in FIG. 12, the global bit line GBL<j> includes a conductive layer 72F.

For example, a cross-sectional area SGBL of the global bit line GBL is larger than the cross-sectional area SWL of the word line WL and the cross-sectional area SBL of the bit line BL. Therefore, a resistivity of a material used in the global bit line GBL is desirably higher than resistivity of a material used in the bit line BL. Materials of the conductive layers 72N and 72F are desirably materials having relatively high resistivities. For example, the materials of the conductive layers 72N and 72F are any one selected from oxides of tantalum (Ta), titanium (Ti), and an oxide of tungsten (W), a nitride of tungsten, an oxide of silicon (Si), and a nitride of silicon.

In order to adjust the length of the global bit line GBL, a position of the column switch SWC and a position of the global switch GYSW on the semiconductor substrate 90 can be appropriately changed.

A width (dimensions in the Y direction) of the global bit line GBL is larger than a width (dimensions in the Y direction) of the bit line BL.

As illustrated in FIGS. 10 to 12, the global bit lines GBL mainly extend in the X direction.

The global bit line GBL<1> has a length (an interconnect length) LX1. The global bit line GBL<yy> has a length LXyy. The global bit line GBL<j> has a length LYj. The length LX1 is longer than the lengths LXyy and LXj. The length LXyy is shorter than the length LX1 and longer than the length LXj. The length LXj is shorter than the lengths LX1 and LXyy.

In this way, the memory cell MCd, which is closer to the row switch circuit 131-1, is connected to the global bit line GBL<1> having a long interconnect length, and the memory cell MCf, which is farther from the row switch circuit 131-1, is connected to the global bit line GBL<j> having a short interconnect length.

Interconnect resistance of the global bit line GBL<1> is higher than interconnect resistance of the global bit line GBL<yy> and interconnect resistance of the global bit line GBL<j>. The interconnect resistance of the global bit line GBL<yy> is lower than the interconnect resistance of the global bit line GBL<1> and higher than the interconnect resistance of the global bit line GBL<j>. The interconnect resistance of the global bit line GBL<j> is lower than the interconnect resistance of the global bit line GBL<1> and the interconnect resistance of the global bit line GBL<yy>.

In a case where a resistance value per unit length of the global bit line GBL is indicated by “RGBL”, the interconnect resistance of the global bit line GBL<1> is “LX1×RGBL”, the interconnect resistance of the global bit line GBL<yy> is “LXyy×RGBL”, and the interconnect resistance of the global bit line GBL<i> is “LXj×RGBL”.

For example, a difference between word line resistance of the memory cell MCd and word line resistance of the memory cell MCf is “(N−1)×Rs_y”. Further, a difference between a resistance value of the global bit line GBL<1> and a resistance value of the global bit line GBL<j> is “(LX1−LXj)×RGBL”.

In a case of offsetting the difference in word line resistance, the magnitude of (LX1−LXj)×RGBL is desirably close to the magnitude of (N−1)×Rs_y. In a case where the magnitude of (LX1−LXj)×RGBL is equal to the magnitude of (N−1)×Rs_y, the influence of the difference in bit line resistance is substantially 0.

In a case where a unit length Lx of the global bit line GBL is indicated to be the same as the pitch between the memory cells MC, “M×RGBL×Lx” is desirably equal to “N×Rs_y”. In the case where N is equal to M, the resistivity per unit length of the global bit line GBL may be equal to the resistivity per unit length of the word line WL.

As described above, a difference in word line resistance corresponding to the coordinates of the memory cell MC in the Y direction is reduced by the difference in interconnect resistance of the global bit lines GBL.

### (b) Operation Example

An operation example of the MRAM 100 of the present embodiment will be described.

The MRAM 100 of the present embodiment receives the command CMD, the address ADR, and various control signals CNT from the external device 900. In a case where the command CMD to be executed is a write operation, the MRAM 100 further receives the write data DT from the external device 900.

The MRAM 100 starts a commanded operation (a write operation or a read operation) based on the command CMD, the address ADR, and various control signals CNT.

The control circuit 180 performs various control operations in response to an operation to be executed based on the command CMD and various control signals CNT. The control circuit 180 decodes the address ADR.

The column control circuit 120 and the row control circuit 130 activate the column switch circuit 121-1 and the row switch circuit 131-1 based on the decoding result of the address ADR.

The memory cell (the selected cell) MC indicated by the address ADR is accessed by the activated column switch circuit 121-1 and the activated row switch circuit 131-1. A voltage and a current used for the operation to be executed are supplied to the selected cell MC via the global bit line GBL, the bit line BL, the global word line GWL, and the word line WL.

The row switch SWR connected to the selected word line WL and the column switch SWC connected to the selected bit line BL are turned on.

During operations on the memory cells MC near the row switch circuit 131-1 and the column switch circuit 121-1 such as the memory cells MC connected to the word line WL<1> and the bit line BL<1>, the word line resistance applied to the memory cell MC and the bit line resistance applied to the memory cell MC are relatively small.

In the present embodiment, as illustrated in FIGS. 7 and 10, the global word line GWL<1> having the long interconnect length LY1 is connected to the selected word line WL (for example, the word line WL<1>) via the row switch SWR, and the global bit line GBL<1> having the long interconnect length LX1 is connected to the selected bit line BL(for example, the bit line BL<1>) via the column switch SWC.

During operations on the memory cells MC far from the row switch circuit 131-1 and the column switch circuit 121-1 such as the memory cells MC connected to the word line WL<M> and the bit line BL<N>, the word line resistance applied to the memory cell MC and the bit line resistance applied to the memory cell MC are relatively large.

In the present embodiment, as illustrated in FIGS. 7 and 10, the global word line GWL<i> having the short interconnect length LYi is connected to the selected word line WL (for example, the word line WL<M>) via the row switch SWR, and the global bit line GBL<j> having the short interconnect length LYj is connected to the selected bit line BL(for example, the bit line BL<N>) via the column switch SWC.

In this way, in the MRAM 100 of the present embodiment, a corresponding one of the plurality of global word lines GWL having different interconnect lengths LY and a corresponding one of the global bit lines GBL having different interconnect lengths LX are connected to the memory cells to be subjected to the operations according to the magnitudes of the word line resistance and the bit line resistance applied to the memory cells in the memory cell array 110.

Accordingly, in the MRAM 100 of the present embodiment, the difference in interconnect resistance corresponding to the coordinates of the memory cell MC is reduced.

### (c) Summary

In the memory cell array having a cross-point structure, the magnitude of the interconnect resistance applied to the memory cell changes corresponding to the coordinates of the memory cell. There is a possibility that a read margin in the plurality of memory cells of the memory cell array is deteriorated due to the difference in interconnect resistance of the memory cells.

The MRAM 100 of the present embodiment includes the plurality of global word lines GWL having different interconnect lengths LY and the plurality of global bit lines GBL having different interconnect lengths LX.

The global word line GWL connected to the memory cell MC and the global bit line GBL connected to the memory cell MC are different corresponding to the coordinates of the memory cell MC.

In a case where the memory cell MC having coordinates close to the row switch circuit 131-1 is selected, the selected memory cell MC is connected to the global bit line GBL<1> having the long interconnect length LX1 via the bit line BL. In a case where the memory cell MC having coordinates far from the row switch circuit 131-1 is selected, the selected memory cell MC is connected to the global bit line GBL<j> having the short interconnect length LXj via the bit line BL.

In a case where the memory cell MC having coordinates close to the column switch circuit 121-1 is selected, the selected memory cell MC is connected to the global word line GWL<1> having the long interconnect length LY1 via the word line WL. In a case where the memory cell MC having coordinates far from the column switch circuit 121-1 is selected, the selected memory cell MC is connected to the global word line WL<i> having the short interconnect length LYi via the word line WL.

Accordingly, the MRAM 100 of the present embodiment can reduce the difference in interconnect resistance applied to the memory cell MC corresponding to the coordinates of the memory cell MC.

As a result, the MRAM 100 of the present embodiment can suppress the deterioration of the read margin.

As described above, the memory device 100 of the present embodiment can reliably improve the operations of the memory cell MC.

### (2) Second Embodiment

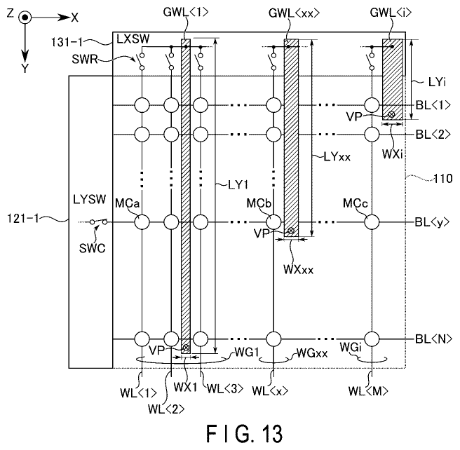

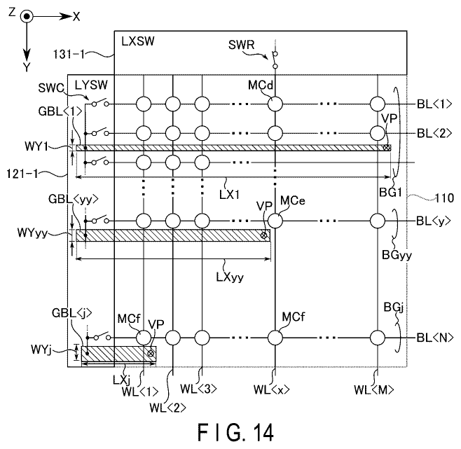

A memory device ac cording to the second embodiment will be described with reference to FIGS. 13 and 14.

FIGS. 13 and 14 are plan views illustrating structural examples of global interconnects GWL and GBL in a memory device (MRAM) 100 of the present embodiment.

As illustrated in FIGS. 13 and 14, a plurality of global interconnects GWL and GBL may have different widths WX (WX1, WXxx, and WXi) and WY (WY1, WYyy, and WYj) from each other in addition to interconnect lengths LY and LX.

As illustrated in FIG. 13, a global word line GWL<1> has a width (an interconnect width) WX1 in an X direction. A global word line GWL<xx> has an interconnect width WXxx in the X direction. A global word line GWL<i> has an interconnect width WXi in the X direction. The interconnect widths WX1, WXxx, and WXi are different from each other.

The interconnect width WX1 is smaller than the interconnect widths WXxx and WXj. The interconnect width WXxx is smaller than the interconnect width WXj and larger than the interconnect width WX1. The interconnect width WXj is larger than the interconnect widths WX1 and WXxx.

The magnitude of interconnect resistance of the global word line GWL changes depending on a size of the interconnect width WX. In a case where the interconnect thickness and the interconnect length are not changed, interconnect resistance of the global word line GWL decreases due to an increase in the interconnect width WX.

Accordingly, interconnect resistance of the global word line GWL<i> becomes further smaller than interconnect resistance of the global word line GWL<1>.

As illustrated in FIG. 14, the global bit line GBL<1> has an interconnect width WY1 in a Y direction. A global bit line GBL<yy> has the interconnect width WYyy in the Y direction. A global bit line GBL<j> has the interconnect width WYj in the Y direction. The interconnect widths WY1, WYyy, and WYj are different from each other.

The interconnect width WY1 is smaller than the interconnect widths WYyy and WYj. The interconnect width WYyy is smaller than the interconnect width WYj and larger than the interconnect width WY1. The interconnect width WYj is larger than the interconnect widths WY1 and WYyy.

The magnitude of interconnect resistance of the global bit line GBL changes depending on a size of the interconnect width WY. In the case where the interconnect thickness and the interconnect length are not changed, a resistance value of the global bit line GBL decreases due to an increase in the interconnect width WY.

Accordingly, interconnect resistance of the global bit line GBL<j> becomes further smaller than the interconnect resistance of the global bit line GBL.

Here, a resistivity of the global word line GWL is indicated by “ρGWL”, and a resistivity of a bit line BL is indicated by “ρBL”. Further, a cross-sectional area of the global word line GWL<1> is indicated by “SGWL1”, and a cross-sectional area of the global word line GWL<i> is indicated by “SGWLi”. A unit length of the bit line BL is indicated by “Lb”.

A difference between bit line resistance of a memory cell MCa connected to a bit line BL<y> and a word line WL<1> and bit line resistance of a memory cell MCc connected to a bit line BL<y> and a word line WL<M> is expressed by the following expression (f1).

$$( M - 1 ) \times ρ BL \times Lb / SBL \qquad ( f 1 )$$

A difference between the interconnect resistance of the global word line GWL<1> and the interconnect resistance of the global word line GWL<i> is expressed by the following expression (f2).

$$ρ GWL \times LY 1 / SGWL 1 - ρ GWL \times LYi / SGWLi \qquad ( f 2 )$$

As described above, since a value of expression (f2) has a value approximate to a value of expression (f1), the difference between the bit line resistance of the memory cell MCa and the bit line resistance of the memory cell MCc is reduced.

It is desirable that the following expression (f3) be satisfied in order to reduce an influence of the difference in the bit line resistance in a memory cell array 110.

$$ρ GWL \times LY 1 / SGWL 1 - ρ GWL \times LYi / SGWLi = ( M - 1 ) \times ρ BL \times Lb / SBL \qquad ( f 3 )$$

Further, a resistivity of the global bit line GBL is indicated by “ρGBL”, and a resistivity of the word line WL is indicated by “ρWL”. Further, a cross-sectional area of the global bit line GBL<1> is indicated by SGBL1, and a cross-sectional area of the global bit line GBL<j> is indicated by SGBLj. A unit length of the word line WL is indicated by “Lw”.

A difference between word line resistance of a memory cell MCd connected to a word line WL<x> and a bit line BL<1> and word line resistance of a memory cell MCf connected to a word line WL<x> and a bit line BL<N> is expressed by the following expression (f4).

$$( N - 1 ) \times ρ WL \times Lw / SWL \qquad ( f 4 )$$

A difference between the interconnect resistance of the global bit line GBL<1> and the interconnect resistance of the global bit line GBL<j> is expressed by the following expression (f5).

$$ρ GBL \times LX 1 / SGBL 1 - ρ GBL \times LXj / SGBLj \qquad ( f 5 )$$

As described above, since a value of the expression (f5) has a value approximate to a value of the expression (f4), a difference between the word line resistance of the memory cell MCd and the word line resistance of the memory cell MCf is reduced.

It is desirable that the following expression (f6) be satisfied in order to reduce an influence of the difference in the word line resistance in the memory cell array 110.

$$ρ GBL \times LX 1 / SGBL 1 - ρ GBL \times LXj / SGBLj = ( N - 1 ) \times ρ WL \times Lw / SWL \qquad ( f 6 )$$

In general, in a semiconductor process, it is difficult to change a film thickness of a conductive layer (an interconnect) in the same hierarchy for each conductive layer. Therefore, as in the present embodiment, it is effective to change resistance values of the global interconnects GWL and GBL by controlling the interconnect widths of the global interconnects GWL and GBL. However, a film thickness of the global word line GWL may be changed for each global word line GWL. Similarly, a film thickness of the global bit line GBL may be changed for each global bit line GBL.

As described above, in the present embodiment, interconnect resistance of the global interconnects is controlled by the interconnect widths in addition to the interconnect lengths. For example, the lengths of the global interconnects GWL and GBL may be limited according to a chip layout or a size of the memory cell array.

Therefore, the MRAM 100 of the present embodiment can flexibly adapt to layout constraints in the chip.

As described above, the memory device 100 of the present embodiment can obtain similar effects to those of the embodiment described above.

### (3) Third Embodiment

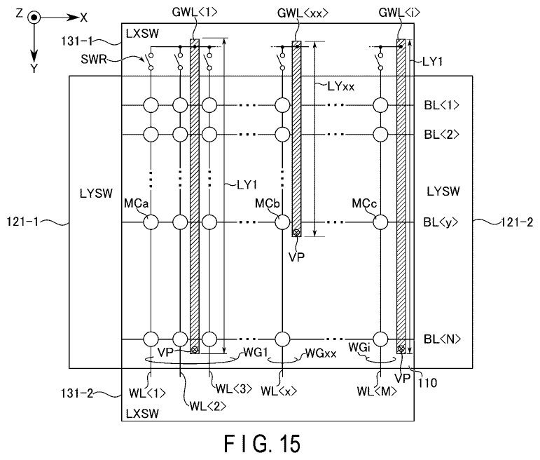

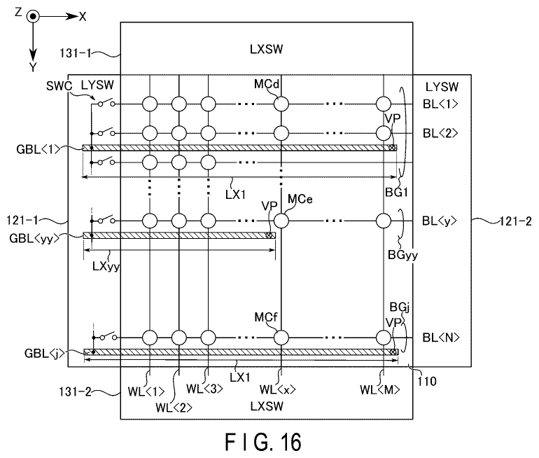

A memory device according to the third embodiment will be described with reference to FIGS. 15 and 16.

FIGS. 15 and 16 are plan views illustrating structural examples of global interconnects GWL and GBL in a memory device (MRAM) 100 of the present embodiment.

As illustrated in FIGS. 15 and 16, the MRAM 100 may include two column switch circuits 121-1 and 121-2 as well as two row switch circuits 131-1 and 131-2.

One column switch circuit 121-1 is disposed on one end side in an X direction of a memory cell array 110. The other column switch circuit 121-2 is disposed on the other end side in the X direction of the memory cell array 110.

In a case where the memory cell array 110 is disposed between the two column switch circuits 121-1 and 121-2, regions on one end side and the other end side in the X direction of the memory cell array 110 are near regions with respect to the column switch circuits 121, and a central region of the memory cell array 110 is a far region with respect to the column switch circuits 121.

For example, during operations on a memory cell MC, one column switch circuit 121 of the two column switch circuits 121-1 and 121-2, which is closer to the selected memory cell MC, is activated.

In this case, as illustrated in FIG. 15, an interconnect length LYxx of a global word line GWL<xx> corresponding to a word line group WGxx at the center in the X direction of the memory cell array 110 is shorter than an interconnect length LY1 of a global word line GWL<1> corresponding to a word line group WG1 on one end side in the X direction of the memory cell array 110, and an interconnect length LY1 of a global word line GWL<i> corresponding to a word line group WGi on the other end side in the X direction of the memory cell array 110. For example, the interconnect length LY1 of the global word line GWL<i> is equal to the interconnect length LY1 of the global word line GWL<1>.

Note that the interconnect width of the global word line GWL<xx> may be different from the interconnect widths of the global word lines GWL<1> and GWL<i>. For example, the interconnect width of the global word lines GWL<xx> is wider than the interconnect widths of the global word lines GWL<1> and GWL<i>.

One row switch circuit 131-1 is disposed at one end of the memory cell array 110 in a Y direction of the array. The other row switch circuit 131-2 is disposed at the other end of the memory cell array 110 in the Y direction.

For example, during operations on a memory cell MC, one column switch circuit 121 of the two column switch circuits 121-1 and 121-2, which is closer to the selected memory cell MC, is activated.

In a case where the memory cell array 110 is disposed between the two row switch circuits 131-1 and 131-2, regions on one end side and the other end side in the Y direction of the memory cell array 110 are near regions with respect to the row switch circuits 131, and a central region of the memory cell array 110 is a far region with respect to the row switch circuits 131.

In this case, as illustrated in FIG. 16, an interconnect length LXyy of a global bit line GBL<yy> corresponding to a central bit line group BGyy in the Y direction of the memory cell array 110 is shorter than an interconnect length LX1 of a global bit line GBL<1> corresponding to a bit line group BG1 on one end side in the X direction of the memory cell array 110 and an interconnect length LX1 of a global bit line GBL<j> corresponding to a bit line group BGj on the other end side in the X direction of the memory cell array 110. For example, the interconnect length LY1 of the global bit line GBL<j> is equal to the interconnect length LY1 of the global bit line GBL<1>.

Note that the interconnect width of the global bit line GBL<yy> may be different from the interconnect widths of the global bit lines GBL<1> and GBL<j>. For example, the interconnect width of the global bit line GBL<yy> is wider than the interconnect widths of the global bit lines GBL<1> and GBL<j>.

Even in a case where the MRAM 100 has a configuration in which the switch circuits 121 and 131 are provided at both ends of the memory cell array 110 as in the present embodiment, the selected memory cell MC can be connected to a corresponding one of the global word lines GWL having different interconnect lengths LY and a corresponding one of the global bit lines GBL having different interconnect lengths LX according to the coordinates of the memory cell MC.

Therefore, the memory device 100 of the present embodiment can obtain substantially the same effects as those of the memory device of the embodiments described above.

### (4) Modification

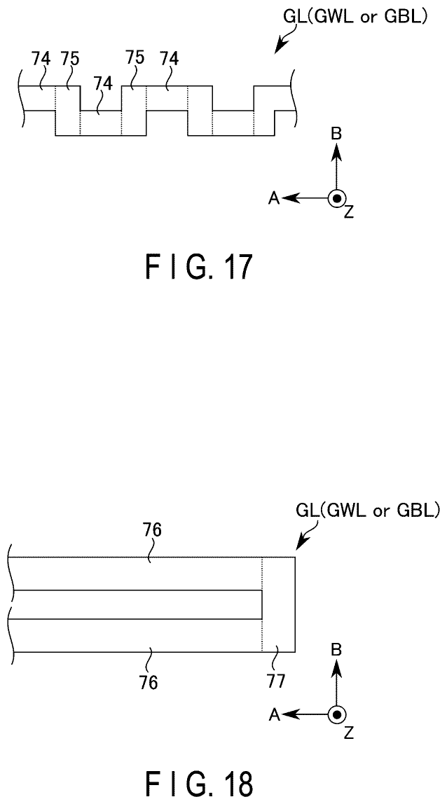

A modification of a memory device according to an embodiment will be described with reference to FIGS. 17 and 18.

FIGS. 17 and 18 are plan views illustrating planar shapes of a global interconnect (a global bit line or a global word line) GL in the modification of the memory device according to the embodiment.

As illustrated in FIG. 17, for a global bit line GBL or a global word line GWL, a global interconnect GL having high interconnect resistance (a long interconnect length) may have a meandering planar shape when viewed from a direction (a Z direction) perpendicular to a semiconductor substrate 90.

The global interconnect GL includes a plurality of portions 74 extending in an A direction (an X direction or a Y direction) and a plurality of portions 75 extending in a B direction (the Y direction or the X direction) intersecting with the A direction. The portions 74 and the portions 75 are alternately arranged in the A direction.

Accordingly, an effective length of the global interconnect GL is increased.

As illustrated in FIG. 18, the global interconnect GL having a high resistance value may have a folded shape when viewed from the Z direction.

The global interconnect GL includes two portions 76 extending in the A direction and a portion 77 extending in the B direction.

The portion 77 connects one portion 76 to the other portion 76 at ends of the two portions 76 in the A direction.

Accordingly, an effective length of the global interconnect GL is increased.

As results of FIGS. 17 and 18, the resistance value of the global interconnect GL increases.

In this way, the resistance values of the plurality of global interconnects GL may be adjusted by controlling the planar shape of the global interconnect GL.

The memory device 100 of the present modification can obtain substantially the same effects as those of the memory devices of the embodiments described above.

### (5) Others

In the embodiments described above, the MRAM is illustrated as the memory device 100 of the present embodiment. However, the memory device 100 of the present embodiment may be a memory device other than the MRAM.

For example, the memory device 100 of the present embodiment may be a memory device (for example, a resistance change memory such as a resistive random access memory (ReRAM)) that uses a transition metal oxide element having variable resistance characteristics as a memory element, a memory device (for example, a phase change memory such as a phase change random access memory (PCRAM)) that uses a phase change element as a memory element, or a memory device (for example, a ferroelectric memory such as a ferroelectric random access memory (FeRAM)) that uses a ferroelectric element as a memory element.

The memory device 100 of the present embodiment can obtain the effects described in the embodiments described above even if the memory device 100 is a memory device other than the MRAM.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory device comprising:
a memory cell array that includes a first local interconnect extending in a first direction, a second local interconnect extending in a second direction intersecting with the first direction, a third local interconnect extending in the second direction, a first memory cell provided between the first local interconnect and the second local interconnect, and a second memory cell provided between the first local interconnect and the third local interconnect;
a first switch circuit that is connected to the first local interconnect and provided on one end side of the memory cell array in the first direction;
a second switch circuit that is connected to the second local interconnect and the third local interconnect and provided on one end side of the memory cell array in the second direction;
a first circuit that executes a write operation or a read operation of the memory cell array; and
a first global interconnect and a second global interconnect that are connected between the second switch circuit and the first circuit,
wherein
the second local interconnect is disposed between the first switch circuit and the third local interconnect in the first direction,
the second local interconnect is connected to the first global interconnect via the second switch circuit,
the third local interconnect is connected to the second global interconnect via the second switch circuit, and
a length of the second global interconnect is shorter than a length of the first global interconnect.

2. The memory device according to claim 1, wherein
a length of the first local interconnect between the second memory cell and the first switch circuit is longer than a length of the first local interconnect between the first memory cell and the first switch circuit.

3. The memory device according to claim 1, further comprising:
a third global interconnect that is connected between the second switch circuit and the first circuit,
wherein
the memory cell array includes:
a fourth local interconnect that extends in the second direction and provided between the second local interconnect and the third local interconnect in the first direction; and
a third memory cell that is provided between the first local interconnect and the fourth local interconnect,
the fourth local interconnect is connected to the third global interconnect via the second switch circuit, and
a length of the third global interconnect is shorter than the length of the first global interconnect and longer than the length of the second global interconnect.

4. The memory device according to claim 1, wherein
a width of the second global interconnect is larger than a width of the first global interconnect.

5. The memory device according to claim 1, further comprising:
a fourth global interconnect and a fifth global interconnect that are connected between the first switch circuit and the first circuit,
wherein
the memory cell array further includes:
a fifth local interconnect that extends in the first direction and disposed between the first local interconnect and the second switch circuit in the second direction; and
a fourth memory cell that is provided between the second local interconnect and the fifth local interconnect,
the first local interconnect is connected to the fourth global interconnect via the first switch circuit,
the fifth local interconnect is connected to the fifth global interconnect via the first switch circuit, and
a length of the fourth global interconnect is shorter than a length of the fifth global interconnect.

6. The memory device according to claim 1, wherein
the memory cell array is provided above a substrate, and
the first global interconnect and the second global interconnect are provided between the memory cell array and the substrate in a third direction perpendicular to a surface of the substrate.

7. The memory device according to claim 1, wherein
the first local interconnect is a first bit line,
the second local interconnect is a first word line,
the third local interconnect is a second word line,
the first switch circuit is a row switch circuit,
the first global interconnect is a first global word line, and
the second global interconnect is a second global word line.

8. The memory device according to claim 1, wherein
the first local interconnect is a first word line,
the second local interconnect is a first bit line,
the third local interconnect is a second bit line,
the first switch circuit is a column switch circuit,
the first global interconnect is a first global bit line, and
the second global interconnect is a second global bit line.

9. The memory device according to claim 1, wherein
resistivities of the first global interconnect and the second global interconnect are higher than resistivities of the first local interconnect to the third local interconnect.

10. The memory device according to claim 1, wherein
the first global interconnect and the second global interconnect have a relationship expressed by the following expression (f0) with respect to the first local interconnect:
$$ρ GWL \times LY 1 / SGWL 1 - ρ GWL \times LYi / SGWLi = ( M - 1 ) \times ρ BL \times Lb / SBL \qquad ( expression f0 )$$
where the ρGWL corresponds to the resistivities of the first global interconnect and the second global interconnect; the LY1 corresponds to an interconnect length of the first global interconnect; the LYi corresponds to an interconnect length of the second global interconnect; the SGWL1 corresponds to a cross-sectional area of the first global interconnect; the SGWLi corresponds to a cross-sectional area of the second global interconnect; the M corresponds to a pitch number in the first direction within the memory cell array; the ρBL corresponds to a resistivity of the first local interconnect; the Lb corresponds to a unit length of the first local interconnect; and the SBL corresponds to a cross-sectional area of the first local interconnect.

11. A memory device comprising:
a memory cell array that includes a first local interconnect extending in a first direction, a second local interconnect extending in a second direction intersecting with the first direction, a third local interconnect extending in the second direction, a fourth local interconnect extending in the second direction, a first memory cell provided between the first local interconnect and the second local interconnect, a second memory cell provided between the first local interconnect and the third local interconnect, and a third memory cell provided between the first local interconnect and the fourth local interconnect;
a first switch circuit that is connected to the first local interconnect and provided on one end side of the memory cell array in the first direction;
a second switch circuit that is connected to the first local interconnect and provided on the other end side of the memory cell array in the first direction;
a third switch circuit that is connected to the second local interconnect, the third local interconnect, and the fourth local interconnect and provided on one end side of the memory cell array in the second direction;
a fourth switch circuit that is connected to the second local interconnect, the third local interconnect, and the fourth local interconnect and provided on the other end side of the memory cell array in the second direction;
a first circuit that executes a write operation or a read operation of the memory cell array; and
a first global interconnect, a second global interconnect, and a third global interconnect that are connected between the third switch circuit and the first circuit,
wherein
the fourth local interconnect is disposed between the second local interconnect and the third local interconnect in the first direction,
the first global interconnect is connected to the second local interconnect via at least one of the third switch circuit and the fourth switch circuit,
the second global interconnect is connected to the third local interconnect via at least the one of the third switch circuit and the fourth switch circuit,
the third global interconnect is connected to the fourth local interconnect via at least the one of the third switch circuit and the fourth switch circuit, and
a length of the third global interconnect is shorter than a length of the first global interconnect and a length of the second global interconnect.

12. The memory device according to claim 11, wherein
the length of the first global interconnect is equal to the length of the second global interconnect.

13. The memory device according to claim 11, wherein
a length of the first local interconnect between the second memory cell and the first switch circuit is longer than a length of the first local interconnect between the first memory cell and the first switch circuit.

14. The memory device according to claim 11, wherein
a width of the third global interconnect is larger than a width of the first global interconnect.

15. The memory device according to claim 11, further comprising:
a fourth global interconnect and a fifth global interconnect that are connected between the first switch circuit and the first circuit,
wherein
the memory cell array further includes:
a fifth local interconnect that extends in the first direction and disposed between the first local interconnect and the third switch circuit in the second direction; and
a fourth memory cell that is provided between the second local interconnect and the fifth local interconnect,
the first local interconnect is connected to the fourth global interconnect via the first switch circuit,
the fifth local interconnect is connected to the fifth global interconnect via the first switch circuit, and
a length of the fourth global interconnect is shorter than a length of the fifth global interconnect.

16. The memory device according to claim 11, wherein
the memory cell array is provided above a substrate, and
the first global interconnect, and the second global interconnect, and the third global interconnect are provided between the memory cell array and the substrate in a third direction perpendicular to a surface of the substrate.

17. The memory device according to claim 11, wherein
the first local interconnect is a first bit line,
the second local interconnect is a first word line,
the third local interconnect is a second word line,
the fourth local interconnect is a third word line,
the first switch circuit is a first row switch circuit,
the second switch circuit is a second row switch circuit,
the third switch circuit is a first column switch circuit,
the fourth switch circuit is a second column switch circuit,
the first global interconnect is a first global word line,
the second global interconnect is a second global word line, and
the third global interconnect is a third global word line.

18. The memory device according to claim 11, wherein
the first local interconnect is a first word line,
the second local interconnect is a first bit line,
the third local interconnect is a second bit line,
the fourth local interconnect is a third bit line,
the first switch circuit is a first column switch circuit,
the second switch circuit is a second column switch circuit,
the third switch circuit is a first row switch circuit,
the fourth switch circuit is a second row switch circuit,
the first global interconnect is a first global bit line,
the second global interconnect is a second global bit line, and
the third global interconnect is a third global bit line.

19. The memory device according to claim 11, wherein
resistivities of the first global interconnect to the third global interconnect are higher than resistivities of the first local interconnect to the third local interconnect.
